(19) United States
(12) Patent Application Publication
(10) Pub. No.: US 2009/0093119 A1
(43) Pub. Date: Apr. 9, 2009

(54) METHOD OF FABRICATING SEMICONDUCTOR DEVICE

(76) Inventor: Kyeong-Jin Lee, Bucheon-si (KR)

Correspondence Address: SHERR & VAUGHN, PLLC, 620 HERNDON PARKWAY, SUITE 200, HERNDON, VA, 20170, US

(21) Appl. No.: 12/245,751

(22) Filed: Oct. 5, 2008

(30) Foreign Application Priority Data
Oct. 9, 2007 (KR) 10-2007-0101446

(51) Int. Cl. H01L 21/461; C23F 1/02

(52) U.S. Cl. 438/692; 156/345.1; 257/E21.483

(57) ABSTRACT

A method of fabricating a semiconductor device is disclosed, by which thickness of a gate oxide layer can be controlled for uniformity. Embodiments include sequentially forming a pad oxide layer and a nitride layer over a semiconductor substrate having an epi-layer grown thereon, the semiconductor substrate having a backside over which a backside nitride layer and a backside oxide layer are formed, forming a trench on the semiconductor substrate, depositing an oxide layer over a front side the semiconductor substrate to fill the trench with the oxide layer, selectively etching the oxide layer, performing a chemical mechanical polishing process on the front side of the semiconductor substrate, performing a chemical mechanical polishing process on the backside of the semiconductor substrate, and forming a gate oxide layer over the semiconductor substrate.

The present application claims priority under 35 U.S.C. 119 to Korean Patent Application No. 10-2007-0101446 (filed on Oct. 9, 2007), which is hereby incorporated by reference in its entirety.

### BACKGROUND

Generally, LOCOS (local oxidation of silicon) may be used for device isolation in fabricating a MOS transistor. Since LOCOS thermally oxidizes a silicon wafer using a nitride layer as a mask, stresses in devices created by an oxide layer are reduced due to a simple process. It is also advantageous because the quality of the generated oxide layer is good.

However, if LOCOS is used, the isolation area is relatively large, putting limitations on device miniaturization. Also, a “bird's beak” phenomenon is created. To overcome these problems, trench isolation methods may replace LOCOS.

In trench isolation, a relatively narrow and deep trench is formed by dry etching such as RIE (reactive ion etch), plasma etching and the like. The trench is filled up with oxide. Thus, a trench is formed on a wafer and is then filed up with oxide. Therefore, the bird's beak related problem is solved. Moreover, the surface of the oxide-filled trench is planarized to reduce the area occupied by an isolation area. Therefore, the trench isolation is advantageous in miniaturizing a device.

A method of fabricating a semiconductor device using a trench according to a related art is explained with reference to the cross-sectional diagrams in FIGS. 1A to 1E as follows. Referring to FIG. 1A, a pad oxide layer 12 may be thermally grown by thermally oxidizing a semiconductor substrate 10 over which a p-type epi-layer 11 has been grown. A nitride layer 14 may be deposited over the pad oxide layer 12. After a moat pattern process has been performed, the nitride and pad oxide layers 14 and 12 may be selectively etched by photolithography. A trench may then be formed on an isolation area of the semiconductor substrate 10 by etching the exposed semiconductor substrate 10 to a predetermined depth. In doing so, a backside oxide layer 9 and a backside nitride layer 8 are formed over a backside of the semiconductor substrate 10 to prevent a p-type epi-layer from growing thereon.

Referring to FIG. 1B, a relatively oxide layer 16 may be deposited over a front side of the semiconductor substrate 10 to fill the trench with the oxide layer 16. Densification may then be performed on the semiconductor substrate.

Referring to FIG. 1C, after a reverse moat pattern process has been performed, the oxide layer 16 may be selectively etched, so that it remains only on the trench area of the semiconductor substrate 10.

Referring to FIG. 1D, the remaining oxide layer 16 may be planarized by chemical mechanical polishing. The nitride and pad oxide layers 14 and 12 may be removed in turn. A gate oxide layer 18 may then be formed over the semiconductor substrate 10.

However, in the related art semiconductor device fabricating method, a gate oxide layer varies in thickness between neighboring devices on a semiconductor substrate. The variations occur due to variations in the thickness of the nitride layer over the backside of the semiconductor substrate. Thus, in the course of the gate oxide process, it is difficult to control the gate oxide layer thickness. Therefore, uniformity of the gate oxide layer is degraded.

### SUMMARY

Embodiments relate to a semiconductor device, and more particularly, to a method of fabricating a semiconductor device. Although embodiments are suitable for a wide scope of applications, they are particularly suitable for controlling thickness of a gate oxide layer for uniformity. Embodiments relate to a method of fabricating a semiconductor device, by which thickness of a gate oxide layer can be uniformly controlled.

Embodiments relate to a method of fabricating a semiconductor device which includes sequentially forming a pad oxide layer and a nitride layer over a semiconductor substrate having an epi-layer grown thereon, the semiconductor substrate having a backside over which a backside nitride layer and a backside oxide layer are formed, forming a trench on the semiconductor substrate, depositing an oxide layer over a front side the semiconductor substrate to fill the trench with the oxide layer, selectively etching the oxide layer, performing a chemical mechanical polishing process on the front side of the semiconductor substrate, performing a chemical mechanical polishing process on the backside of the semiconductor substrate, and forming a gate oxide layer over the semiconductor substrate.

Accordingly, a semiconductor device fabricating method according to embodiments prevents variations in thickness of a gate oxide layer between neighboring semiconductor devices. The variations are in turn due to thickness variations in a nitride layer over a backside of a semiconductor substrate. Embodiments use backside CMP prior to formation of a gate oxide layer, thereby controlling the thickness of the gate oxide layer for uniformity. Moreover, embodiments may prevent a gate oxide layer from being scratched, thereby raising process yields of a gate oxide layer process.

### DRAWINGS

FIGS. 1A to 1E are cross-sectional diagrams for a method of fabricating a semiconductor device according to a related art; and

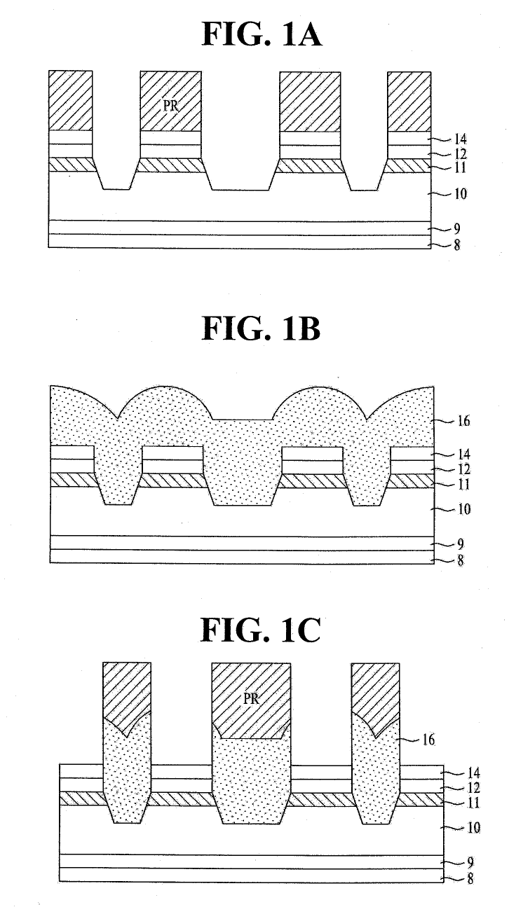

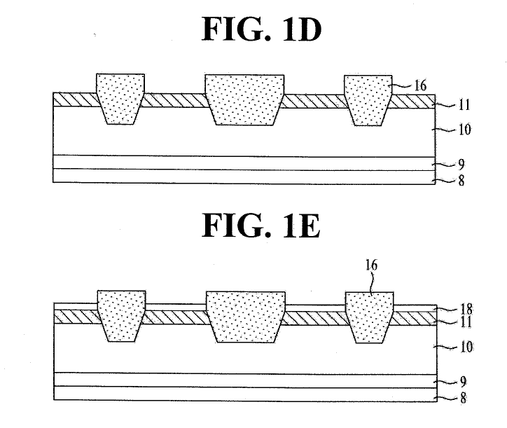

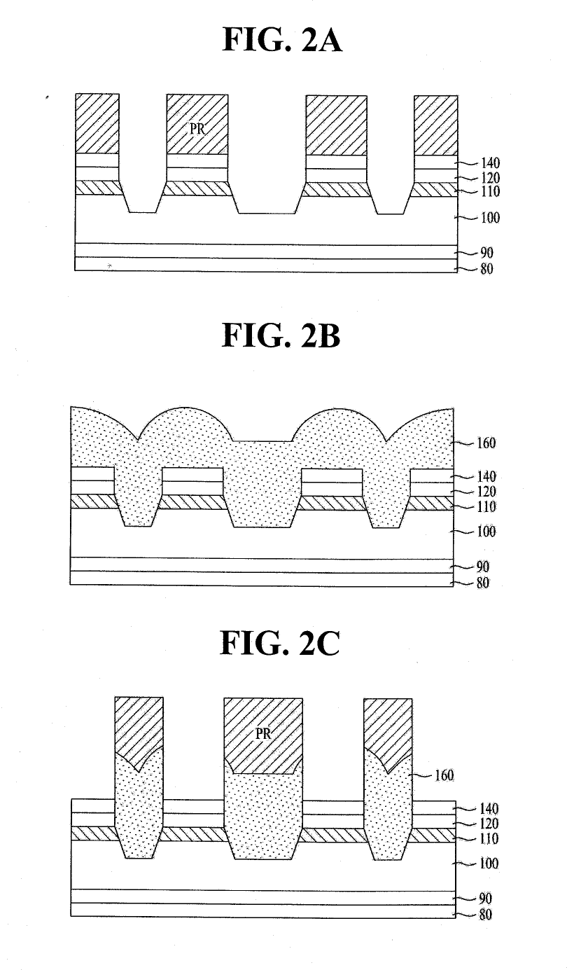

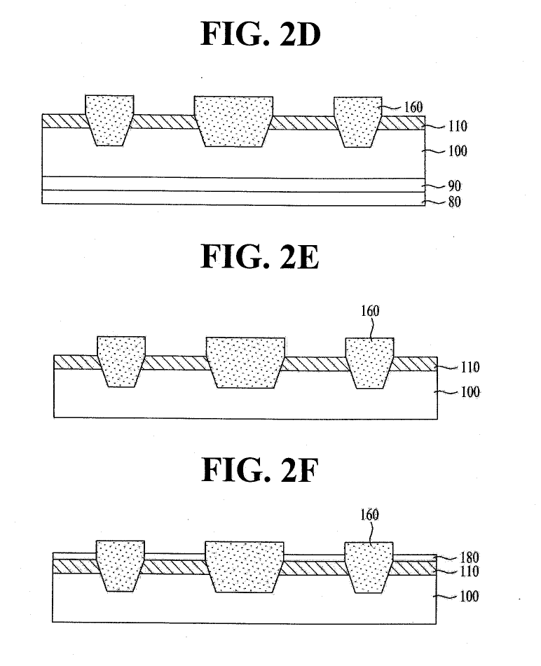

Example FIGS. 2A to 2F are cross-sectional diagrams for a method of fabricating a semiconductor device according to the present invention.

### DESCRIPTION

Example FIGS. 2A to 2F are cross-sectional diagrams for a method of fabricating a semiconductor device according to the present invention.

Referring to example FIG. 2A, a pad oxide layer 120 may be thermally grown by thermally oxidizing a semiconductor substrate 100 over which a p-type epi-layer 110 has been grown. A nitride layer 140 may be deposited over the pad oxide layer 120. After a moat pattern process has been performed, the nitride and pad oxide layers 14 and 12 may be selectively etched by photolithography using a photoresist pattern for exposing an isolation area of the semiconductor substrate. A trench may then be formed on the isolation area of the semiconductor substrate 100 by etching the exposed semiconductor substrate 100 to a predetermined depth. In doing so, a backside oxide layer 90 and a backside nitride layer 80 may be formed over a backside of the semiconductor substrate 10 to prevent a p-type epi-layer from growing thereon.

Referring to example FIG. 2B, a relatively thick oxide layer 160 may be deposited over a front side of the semiconductor substrate 100 to fill the trench with the oxide layer 160. Densification may then be performed over the semiconductor substrate.

Referring to example FIG. 2C, after a reverse moat pattern process has been performed, the oxide layer 16 may be selectively etched by photolithography using a photoresist pattern for exposing the semiconductor substrate 100. The isolation area is not exposed, so that the oxide remains only on the trench area of the semiconductor substrate 10.

Referring to example FIG. 2D, after the photoresist pattern has been removed, the semiconductor substrate 100 may be planarized by chemical mechanical polishing. The nitride and pad oxide layers 140 and 120 may then be removed in turn.

Referring to example FIG. 2E, by removing the backside oxide and nitride layers 90 and 80 over the backside of the semiconductor substrate 100 by CMP, the backside of the semiconductor substrate 100 is planarized.

Referring to example FIG. 2F, a gate oxide layer 180 is then formed over the semiconductor substrate 100 except the isolation area of the semiconductor substrate 100.

Accordingly, in embodiments, backside oxide and nitride layers may be removed from a backside of a semiconductor substrate prior to formation of a gate oxide layer. The backside of the semiconductor substrate may then be planarized by CMP. Therefore, embodiments prevent a gate oxide layer over a semiconductor substrate from varying in thickness between neighboring devices due to variations in the thickness of the nitride layer over the backside of the semiconductor device. Thus, the thickness of the gate oxide layer may be controlled to be relatively uniform.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
sequentially forming a pad oxide layer and a nitride layer over front side of a semiconductor substrate having an epi-layer grown thereon, the semiconductor substrate having a backside over which a backside nitride layer and a backside oxide layer are formed;
forming a trench on the front side of the semiconductor substrate;
depositing an oxide layer over a front side the semiconductor substrate to fill the trench with the oxide layer;
selectively etching the oxide layer;
performing a chemical mechanical polishing process on the front side of the semiconductor substrate;
performing a chemical mechanical polishing process on the backside of the semiconductor substrate; and
forming a gate oxide layer over the front side of the semiconductor substrate.

2. The method of claim 1, comprising removing the pad oxide layer and the nitride layer sequentially after said performing the chemical mechanical polishing process on the front side of the semiconductor substrate.

3. The method of claim 2, wherein the pad oxide layer and the nitride layer are removed by wet etch.

4. The method of claim 1, wherein said performing the chemical mechanical polishing process on the backside of the semiconductor substrate comprises removing the backside nitride layer and the backside oxide layer.

5. The method of claim 1, wherein the gate oxide layer is formed over the semiconductor substrate, but the oxide layer is not formed over an isolation area.

6. The method of claim 1, wherein said depositing the oxide layer comprises:
filling the trench with the oxide layer; and
performing densification over the semiconductor substrate including the oxide layer.

7. The method of claim 1, wherein said selectively etching the oxide layer comprises etching the oxide layer so that the oxide layer remains only over a trench area of the semiconductor substrate.

8. The method of claim 1, wherein said forming the trench comprises:
exposing a trench area of the semiconductor substrate by selectively etching the nitride layer and the pad oxide layer; and
etching the trench area of the semiconductor substrate to a predetermined depth.

9. The method of claim 1, wherein the pad oxide layer is thermally grown by thermally oxidizing the semiconductor substrate.

10. The method of claim 1, wherein the trench filled with an oxide layer forms an isolation region.

11. An apparatus configured to:
sequentially form a pad oxide layer and a nitride layer over a semiconductor substrate having an epi-layer grown thereon, the semiconductor substrate having a backside over which a backside nitride layer and a backside oxide layer are formed;
form a trench on the semiconductor substrate;
deposit an oxide layer over a front side the semiconductor substrate to fill the trench with the oxide layer;
selectively etch the oxide layer;
perform a chemical mechanical polishing process on the front side of the semiconductor substrate;
perform a chemical mechanical polishing process on the backside of the semiconductor substrate; and
form a gate oxide layer over the semiconductor substrate.

12. The apparatus of claim 11, wherein the apparatus is configured to remove the pad oxide layer and the nitride layer sequentially after performing said chemical mechanical polishing process on the front side of the semiconductor substrate.

13. The apparatus of claim 12, wherein the apparatus is configured to remove the pad oxide layer and the nitride layer by wet etch.

14. The apparatus of claim 11, wherein the apparatus is configured to perform said chemical mechanical polishing process on the backside of the semiconductor substrate by removing the backside nitride layer and the backside oxide layer.

15. The apparatus of claim 11, wherein the apparatus is configured to form the gate oxide layer over the semiconductor substrate, but not over an isolation area.

16. The apparatus of claim 11, wherein the apparatus is configured to deposit said oxide layer by:
filling the trench with the oxide layer; and
performing densification over the semiconductor substrate including the oxide layer.

17. The apparatus of claim 11, wherein the apparatus is configured to selectively etching said oxide layer by etching the oxide layer so that the oxide layer remains only over a trench area of the semiconductor substrate.

18. The apparatus of claim 11, wherein the apparatus is configured to form said trench by:
exposing a trench area of the semiconductor substrate by selectively etching the nitride layer and the pad oxide layer; and
etching the trench area of the semiconductor substrate to a predetermined depth.

19. The apparatus of claim 11, wherein the apparatus is configured to thermally grow said pad oxide layer by thermally oxidizing the semiconductor substrate.

20. A method comprising:
sequentially forming a pad oxide layer and a nitride layer over a semiconductor substrate having an epi-layer grown thereon, the semiconductor substrate having a backside over which a backside nitride layer and a backside oxide layer are formed;
exposing a trench area of the semiconductor substrate by selectively etching the nitride layer and the pad oxide layer;
etching the trench area of the semiconductor substrate to a predetermined depth to form a trench;
depositing an oxide layer over a front side the semiconductor substrate to fill the trench;
performing densification over the semiconductor substrate including the oxide layer;
selectively etching the oxide layer so that the oxide layer remains only over a trench area of the semiconductor substrate;
performing a chemical mechanical polishing process on the front side of the semiconductor substrate;
sequentially removing the pad oxide layer and the nitride layer by wet etch;
performing a chemical mechanical polishing process on the backside of the semiconductor substrate thereby removing the backside nitride layer and the backside oxide layer; and
selectively forming a gate oxide layer over the semiconductor substrate.
